(19) United States
(12) Patent Application Publication
(10) Pub. No.: US 2017/0345977 A1
(43) Pub. Date: Nov. 30, 2017

(54) CONVERSION ELEMENT AND PRODUCTION METHOD THEREOF

(71) Applicant: OSRAM Opto Semiconductors GmbH, Regensburg (DE)

(72) Inventors: Britta GOEOETZ, Regensburg (DE); Frank SINGER, Regenstauf (DE); Joachim WIRTH-SCHOEN, Guenzburg (DE)

(21) Appl. No.: 15/527,320

(22) PCT Filed: Nov. 13, 2015
(86) PCT No.: PCT/EP2015/076586

§ 371 Date: May 16, 2017

(30) Foreign Application Priority Data
Nov. 17, 2014 (DE) 10 2014 116 778.3

(51) Int. Cl. H01L 33/50

(52) U.S. Cl. CPC H01L 33/505; H01L 33/508; H01L 33/502; H01L 33/507; H01L 2933/0041

(57) ABSTRACT

A method for the production of a conversion element (3) is disclosed, which comprises the following steps: A) provision of a first covering member (1) which has a first connecting surface (1a) and of a second covering member (2), B) insertion of at least one cavity (10) into the first covering member (1) on the first connecting surface (1a), C) filling of the at least one cavity (10) with a filling compound (30), which comprises a conversion material (31), D) applying of the second covering member (2) to the first connecting surface (1a) of the first covering member (1), E) cohesive connection of the first covering member (1) and of the second covering member (2).

Patent specification DE 10 2012 110 668 describes a method for producing a conversion element as well as an optoelectronic component having a conversion element.

One object to be achieved consists in providing a conversion element having a longer operational lifetime. Other objects to be achieved consist in providing an optoelectronic component having such a conversion element as well as a method for producing such a conversion element.

A method for producing a conversion element is provided. In particular, the conversion element is an optical component, which is provided for the conversion of the wavelength of light entering the conversion element. For example, the light entering the conversion element can be scattered on scattering particles in the conversion element—which will hereinafter be referred to as conversion material—and the wavelength of the light can be changed by this scattering. Preferably, the wavelength of the entering light is increased by the conversion and/or the spectral range of the entering light is widened by the conversion.

According to at least one embodiment of the method, first a first cover body with a first connecting surface and a second cover body with a second connecting surface are provided. The first cover body and the second body are preferably in each case formed of a light-transmissive material or consist of a light-transmissive material. The light-transmissive material is glass, for example. The cover body and the second cover body preferably are in each case glass plates, for example.

Here and in the following, a material is formed to be “light transmissive” if it transmits at least 90%, preferably at least 95%, of a visible light entering the material. On the other hand, a material is formed to be “light-absorbent” or “light-reflecting” if at least 90%, preferably at least 95%, of the visible light entering the material is absorbed or reflected by the material, respectively.

The first cover body and the second cover body each have a main extension plane in which they extend in the lateral direction. The first cover body and the second cover body each have a thickness perpendicular to the main extension plane. The thickness of the first cover body and the thickness of the second cover body are each small compared to the maximum extension of the respective cover bodies in a lateral direction. The first connecting surface forms a main plane of the first cover body and the second connecting surface forms a main plane of the second cover body. Preferably, the first cover body and the second cover body have a similar lateral extent. For example, the lateral extents of the first cover body and the second cover body differ by no more than 10%.

According to at least one embodiment of the method, a cavity is formed in the first cover body on the side of the first cover body that comprises the first connecting surface. To that end, a part of the material is removed from the first cover body, or the first cover body is deformed for forming the cavity, e.g. by deep-drawing.

In particular, the cavity is a depression in the first cover body, wherein the depression does not completely penetrate the first cover body in the vertical direction. In other words, after forming the cavity, a first outer surface of the first cover body facing away from the first connecting surface is still formed to be one-connected. The first cover body may have a smaller thickness in the region of the cavity than in the region outside the cavity. For example, the first cover body has a thickness in the region of the cavity that corresponds to at least 30%, preferably at least 40%, and no more than 90%, preferably no more than 70%, of the thickness of the first cover body in the region outside the cavity. Forming the cavity is carried out with a rolling technique and/or an etching process, for example.

According to at least one embodiment of the method, the at least one cavity is filled with a filling material. The filling material may be a polymer solution, for example. For example, filling the at least one cavity with the filling material can be performed using a casting method, e.g. by means of dosing, printing and/or spraying. After filling the cavity, the filling material can be cured, e.g. by heating.

A conversion material is introduced in the filling material. The conversion material serves for the above-described wavelength conversion of the wavelength of a light entering the conversion element. Preferably, the peak wavelength of the light entering the conversion element is converted in such a way that the peak wavelength of the converted light is at least 10 nm, preferably at least 50 nm, greater than the peak wavelength of the entering light. Preferably, the conversion material is a sensitive conversion material. The conversion material is formed with scattering particles or consists of scattering particles, for example. Here and in the following, “scattering particles” can particularly be particles, the size of which in at least one spatial direction is not greater than the dimension of the wavelength of the light to be scattered. For example, at least 90% of the scattering particles in each spatial direction have a size of at least 50 nm and maximum 1 μm.

According to at least one embodiment of the method, the second cover body is applied to the first connecting surface of the first cover body. Here, the second connecting surface faces the first connecting surface. The application is preferably effected in such a way that afterwards, the first cover body and the second cover body are in direct contact to one another at least in places.

After the application, the second cover body may entirely overlap and/or cover the filling material on the cover surface thereof facing away from the first cover body. In particular, the first cover body and the second cover body overlap and/or cover the filling material in the vertical direction. Laterally, the filling material can be enclosed by the first cover body, in particular by side surfaces of the cavity.

According to at least one embodiment of the method, the first cover body and the second cover body are cohesively connected to one another. Here and in the following, a “cohesive connection” is a connection, in which the connection partners are held together, inter alia, by atomic and/or molecular forces. In particular, a hermetic seal of a free space between two connecting partners can be effected by a cohesive connection. For example, a cohesive connection is a van-der-Waals-connection. Furthermore, it is possible that the cohesive connection is an adhesive connection and/or a fused connection. For example, a cohesive connection can in particular not be released in a non-destructive manner. In other words, the connecting partners can only be separated from one another using a chemical solvent and/or by destruction.

According to at least one embodiment of the method for producing a conversion element, the method comprises the following steps:
A) providing a first cover body with a first connecting surface and second cover body,
B) forming at least one cavity in the first cover body on the first connecting surface,
C) filling the at least one cavity with a filling material, which comprises a conversion material,
D) applying the second cover body to the first connecting surface of the first cover body,
E) cohesively connecting the first cover body and the second cover body.

Preferably, the indicated method steps are carried out in the indicated order.

According to at least one embodiment of the method, the water vapor transmission rate into the cavity and/or into the filling material is no more than 1×10⁻³ g/m²/day, preferably no more than 3×10⁻⁴ g/m²/day. In other words, the cavity is hermetically sealed toward the outside. Thus, the filling material and/or the conversion material are also hermetically sealed toward the outside. To that end, the filling material can be entirely enclosed by the material of the first and/or the second cover body. Preferably, the material of the first cover body, the material of the second cover body and a possibly present cohesively-connecting material between the first cover body and the second cover body have a water vapor transmission rate of at least 1×10⁻³ g/m²/day, preferably 3×10⁻⁴ g/m²/day.

In the present invention, in particular the idea of providing a conversion element with a hermetically sealed sensitive conversion material is pursued. The sensitive conversion material can be wavelength-converting quantum dots and/or an organic conversion material, for example.

In such sensitive conversion materials, there is the problem that these sensitive materials can be destroyed by the intrusion of air and/or moisture from the surroundings into the conversion material or in the filling material, respectively. In particular, the wavelength-converting properties, such as the efficiency of the wavelength conversion of the conversion material can be deteriorated. The intrusion of air and/or moisture into the filling material and thus a destruction of the wavelength-converting properties of the conversion material can be prevented by filling a filling material including the conversion material into a hermetically sealed cavity. The operational lifetime of the conversion element, and in particular the operational lifetime of the conversion material, can thereby be increased.

According to at least one embodiment of the method, the cavity has a depth which corresponds to at least 10%, preferably at least 20%, of the thickness of the first cover body. The depth of the cavity may correspond to no more than 90%, preferably no more than 70%, and particularly preferably no more than 50%, of the thickness of the first cover body. The depth of the cavity is given by the reduced thickness of the first cover body in the region of the cavity. In particular, the depth of the cavity corresponds to the point where the cover body has the smallest thickness. In order words, the cavity is a depression that is introduced in the first cover body.

According to at least one embodiment of the method, the conversion material comprises wavelength-converting quantum dots or consists of wavelength-converting quantum dots. Wavelength-converting quantum dots are a sensitive conversion material. Preferably, the quantum dots are nanoparticles, i.e. particles having a size in the nanometer range. The quantum dots include a semiconductor core which has wavelength-converting properties. The semiconductor core can be formed with CDSE, CDS, EANS and/or ENP, for example. The semiconductor core can be coated by several layers. In other words, the semiconductor core can completely or almost completely be covered by further layers on the outer surfaces thereof.

A first enclosing layer of a quantum dot is formed with an inorganic material, e.g. ZNS, CDS and/or CDSE, and serves for the generation of the quantum dot potential. The first enclosing layer and the semiconductor core are almost entirely enclosed by at least a second enclosing layer at the exposed outer surface. The second layer can be formed with an inorganic material such as cystamine or cysteine, and, inter alia, serves to improve the solubility of the quantum dots in e.g. a matrix material and/or a solvent. It is possible here that a uniform three-dimensional distribution of the quantum dots in a matrix material is improved due to the second enclosing layer.

Here, there is the problem that the second enclosing layer of the quantum dot could oxidize and thus be destroyed when in contact with air, whereby the solubility of the quantum dots would be reduced. This would lead to an agglomeration of the quantum dots, i.e. to a formation of lumps, in the matrix material. In the case of lump-formation, the quantum dots would come too close to one another in the matrix material and the excitation energies could be exchanged between the quantum dots without radiation. This would result in a loss of efficiency in the wavelength conversion.

The destruction of the second enclosing layer can be prevented by hermetically sealing the quantum dots from the air surrounding the conversion element. In the present case, this hermetic sealing is effected by the cohesive connection of the two cover bodies.

Additionally or alternatively to the quantum dots as a conversion material, the conversion element may contain an organic conversion material. The organic conversion material can be organic colorants, for example. Such organic colorants are known from the German patent publication DE 10 2007 049 005 A1, for example, the disclosure content of which is incorporated herein by reference.

According to at least one embodiment of the method, the filling of the cavity in step C) is effected in such a way that the cover surface of the filling material terminates flush with the first connecting surface of the first cover body and the second cover body is in direct contact with the cover surface after connecting the two cover bodies in step E). In other words, the cavity is preferably completely filled with the filling material, wherein the filling material does not protrude from the cavity in the vertical direction. If the filling material is cured, it is possible that the filling material protrudes from or reaches below the cavity prior to the curing and that the flush termination of the filling material is formed only after the curing process. A direct contact between the second connecting surface of the second cover body and the cover surface of the filling material may develop by the complete filling when connecting the two cover bodies in step E). An inclusion of air in the cavity can thereby be prevented.

According to at least one embodiment of the method, the connection of the first cover body and the second cover body in step E) is effected by means of wringing and/or cold welding. In wringing, two smooth, even surfaces, in this case the first connecting surface and the second connecting surface are connected only by their molecular forces of attraction. In particular, the connecting surfaces must be free from dust, fat and/or other contaminations. In particular, van-der-Waals forces develop between the first cover body and the second cover body by the wringing and/or cold welding processes. A cohesive connection can be provided thereby, which is free from joining material, such as an adhesive, between the first cover body and the second cover body.

According to at least on embodiment of the method, the first connecting surface and the second connecting surface are treated with a solvent prior to application of the second cover body to the first cover body in step D). Tetrachloroethene and/or acetone are used as the solvent, for example. By the treatment with a solvent, the first connecting surface and the second connecting surface can, in particular, be cleaned, and thus smooth and contamination-free connecting surfaces can be provided. This enables the connection of the two cover bodies by means of wringing.

Alternatively, or additionally, the first cover body and the second cover body are heated at up to a temperature of typically 23° C. and/or radiated with ultrasound-radiation after the application in step D). In particular, the temperature is at least 21° C., preferably at least 22° C., and no more than 25° C., preferably no more than 24° C. Furthermore, humidity of the ambient air can be at least 45% and no more than 55%. This treatment of the two cover bodies promotes, inter alia, the formation of the connecting van-der-Waals forces between the two connecting surfaces.

According to at least one embodiment of the method, the application of the second cover body to the first cover body in step D) is effected at an ambient pressure of at least 10⁻³ Pa, preferably at least 10⁻² Pa, and particularly preferably no more than 10⁻¹ Pa, and no more than 10⁵ Pa, particularly preferably no more than 10³ Pa, and particularly preferably no more than 10² Pa. By joining below atmospheric pressure, or respectively vacuum, it is particularly possible to connect the two cover bodies using cold welding and/or wringing.

According to at least one embodiment of the method, a plurality, i.e. at least two, laterally spaced cavities is formed in the first cover body, wherein at least one of the plurality of cavities remains free from the filling material. After completion of the production method, the conversion element then comprises multiple cavities, at least one of which is free from the filling material. The at least one cavity that is free from the filling material can be filled with air and/or a gas.

The cavity that is filled with air is suitable, for example, to scatter scattering light away from a main radiation direction of an optoelectronic component comprising the conversion element having the plurality of cavities. Furthermore, it is possible that the cavities are singulated in the conversion element. Thereby, multiple conversion elements can be produced, one of which comprises at least one cavity that does not contain the filling material.

According to at least one embodiment of the method, the connection of the first cover body and the second cover body in step E) is effected under exclusion of a joining material, in particular an adhesive. The first connecting surface and the second connecting surface are free from a joining material. In particular, the first connecting surface and the second connecting surface are directly adjacent to one another after the connection of the first cover body and the second cover body. The connection is then established only via atomic and/or molecular forces between the first connecting surface and the second connecting surface, for example.

According to at least one embodiment of the method, the connection in step E) is effected by laser welding with a pulsed laser beam. The pulsed laser beam may be a pico-second or a femtosecond laser beam, for example. Thus, alternatively or in addition to the wringing and/or cold welding, the connection between the first cover body and the second cover body can be established by fusing with a laser beam. A weld seam may develop, which encloses the filling material laterally at least in places. In particular, the filling material can be entirely enclosed by the weld seam.

Furthermore, a conversion element is provided. Preferably, the conversion element can be produced by means of a method described herein. In other words, all features disclosed for the method are also disclosed for the conversion element and vice versa.

According to at least one embodiment of the conversion element, the conversion element comprises the first cover body with the first connecting surface and the second cover body with the second connecting surface facing the first cover body. The first cover body and the second cover body are cohesively connected to one another. Preferably, the first cover body and the second cover body have similar lateral extents. The maximum extent of the conversion element along the lateral directions can be given in particular by the maximum extent of the first cover body and the second cover body along the lateral directions.

In the first cover body, the cavity is formed on the first connecting surface, with the filling material with the conversion material being introduced therein. The cavity and/or the filling material are enclosed by the first cover body and the second cover body in the vertical direction. In the lateral direction, the cavity is enclosed by the first cover body and the second cover body as well. Preferably, the cavity and/or the filling material are entirely enclosed by the first and the second cover body and hermetically sealed by said filling material toward the outside.

According to at least one embodiment of the conversion element, a weld seam is arranged between the first cover body and the second cover body, which encloses the filling material in the type of a frame. In particular, the filling material is laterally entirely enclosed by the weld seam. Here and in the following, the phrase “enclose in the type of a frame” means the weld seam entirely surrounds the filling material laterally.

According to at least one embodiment of the conversion element, the filling material has a thickness that corresponds to at least 10%, preferably at least 20%, and no more than 90%, preferably no more than 80%, and particularly preferably no more than 50% of the thickness of the first cover body. The thickness of the filling material or the thickness of the first cover body are in each case the extents of the filling material or the first cover body in the vertical direction.

According to at least one embodiment of the conversion element, a plurality of cavities is present in the first cover body, wherein at least one of the plurality of cavities is free from the filling material. This at least one cavity, which is free from the filling material, can be filled with air and/or a gas, for example. In particular, the at least one cavity, which is free from the filling material, does not contain a conversion material.

According to at least one embodiment of the conversion element, the first connecting surface and the second connecting surface are directly adjacent to one another and are free from a connecting material. Preferably, all regions of the first connection surface and the second connecting surface that are free from the filling material and/or the cavity are directly adjacent to one another. In the region of the filling material, the second connecting surface can be directly adjacent to the cover surface of the filling material. In other words, preferably, no free space filled with air and/or gas is arranged between the filling material and the second cover body.

Furthermore, an optoelectronic component is provided. The optoelectronic component can be a light-emitting component, which comprises organic and/or inorganic materials for the generation of light. The optoelectronic component is an organic or inorganic light-emitting diode, for example. The optoelectronic component comprises a conversion element described herein. All features disclosed for the conversion element and the method are thus also disclosed for the optoelectronic component and vice versa.

According to at least one embodiment of the optoelectronic component, the optoelectronic component comprises at least one conversion element. Furthermore, the optoelectronic component comprises at least one light-emitting component. The light-emitting component comprises a light exit surface. The light exit surface is provided in particular for the out-coupling of the light generated in the light-emitting component. In particular, the light-emitting component can be a light-emitting diode component.

In particular, it is possible that the light-emitting component is a so-called “semiconductor chip in a frame” component. Such a component is described, e.g., in patent specification DE 10 2012 215 524 A1, the disclosure content of which is incorporated herein by reference. In particular, a “semiconductor chip in a frame” component comprises a shaped body, which can be formed with a silicone and/or an epoxy resin, for example. Such materials have the disadvantage that they are not formed to be hermetically sealing, which is why air and/or moisture can enter the shaped body. In the case that a not hermetically-sealing conversion element is used in such a “semiconductor chip in a frame” component, use of a sensitive conversion material may result in the destruction of the conversion material.

According to at least one embodiment of the optoelectronic component, the component comprises a light-transmissive connection layer. The light-transmissive connection layer may be an adhesive layer, which is formed with a silicone, for example. The light-transmissive connection layer entirely covers the component on the side that comprises the light exit surface.

Furthermore, an outer surface of the conversion element is directly adjacent to a joining surface of the connection layer facing away from the component. The outer surface of the conversion element can be a first bottom surface of the first cover body facing away from the first connecting surface or a second bottom surface of the second cover body facing away from the second connecting surface, for example. Thus, the conversion element is arranged behind the component at the light exit surface thereof. In other words, light that is decoupled from the component, can be coupled in the filling material and be converted therein by means of the conversion material.

According to at least one embodiment of the optoelectronic component, the component comprises at least one conversion element, at least one light-emitting component having a light exit surface, and a light-transmissive connection layer, wherein the connection layer completely covers the component on the side that comprises the light exit surface and an outer surface of the conversion element is directly adjacent to a joining surface of the connecting layer facing away from the component.

According to at least one embodiment of the optoelectronic component, the first cover body of the conversion element comprises at least one first cavity and at least one second cavity that is laterally spaced from the first cavity. The filling material is introduced in the at least one first cavity. The at least one second cavity is filled with air and/or a gas. The second cavity is thus free from the filling material.

The filling material of the first cavity and/or the second cavity are arranged directly behind the light exit surface. In particular, the filling material is arranged directly behind the light exit surface in a main radiation direction of the light-emitting component. In other words, at least 80%, preferably at least 90% of the light emitted by the light-emitting component in the direction of the conversion element is coupled into the filling material. Furthermore, the filling material completely covers the light exit surface. In particular, the filling material completely covers the light exit surface in a plan view from a vertical direction. This enables to efficiently couple the light generated by the light-emitting component into the filling material of the conversion element.

The second cavity is arranged laterally spaced from the light-emitting component. Preferably, the lateral distance to the component is that great that at least 5%, preferably at least 2%, of the light emitted by the light-emitting component directly in the direction of the conversion element, i.e. not scattered and/or reflected light, gets into the second cavity. However, it is possible that scattering light is coupled into the second cavity. In particular, a diffuser lens effect is achieved by the refraction at the interfaces between the material of the first cover body, the gas and/or the air in the second cavity and/or the material of the second cover body. As a result, scattered light can be refracted away from the main radiation direction, and thus an optoelectronic component having a directed radiation characteristic can be provided.

Hereinafter, the method for producing a conversion element described herein, the conversion element described herein and the optoelectronic component described herein will be described in more detail on the basis of exemplary embodiments and the corresponding figures.

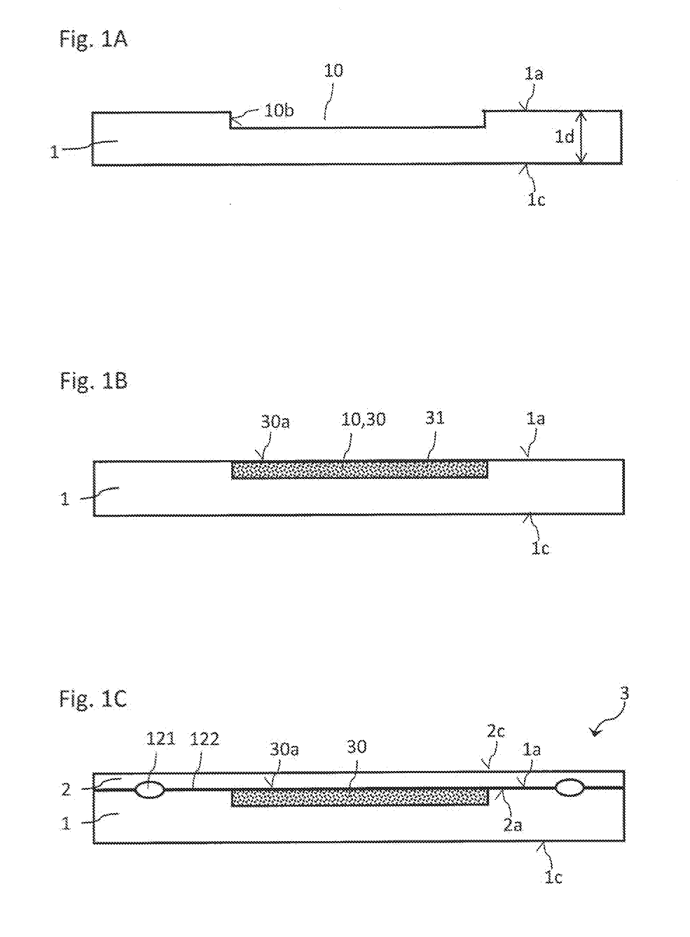

The FIGS. 1A to 1C show an exemplary embodiment of a method for producing a conversion element described herein as well as an exemplary embodiment of a conversion element described herein on the basis of schematic sectional illustrations.

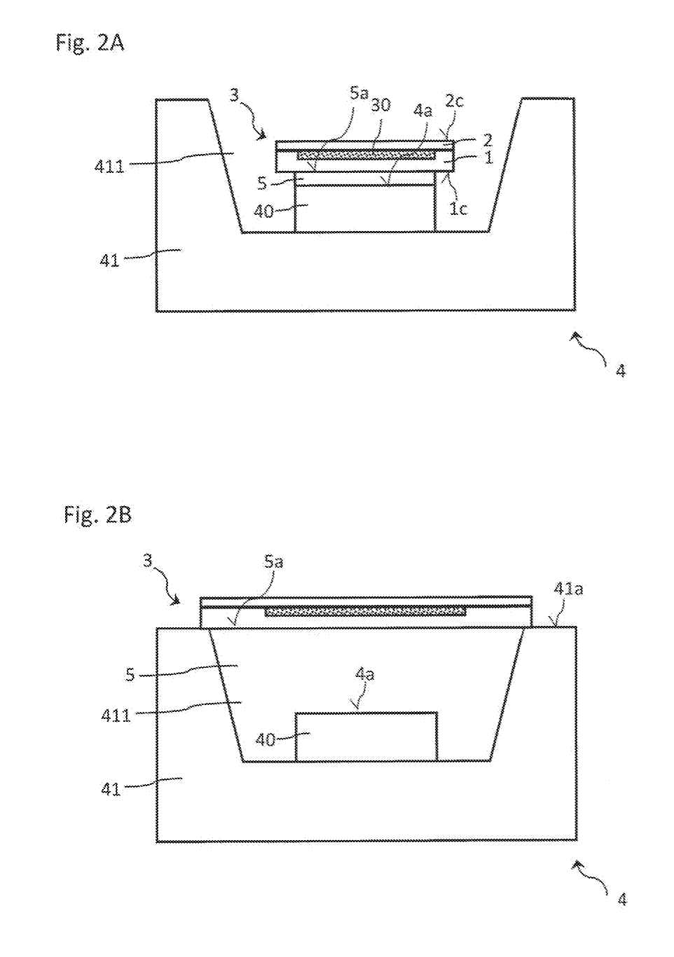

The FIGS. 2A, 2B, 3A, 3B, 4 show exemplary embodiments of a conversion element described herein as well as of an optoelectronic component described herein on the basis of schematic sectional illustrations.

Like, similar or equivalent elements are provided with the same reference numerals throughout the figures. The figures and the dimensional relations among the elements shown are not considered to be to scale. Individual elements may rather be illustrated in an exaggerated size for a better understanding and/or better illustration.

According to the schematic sectional illustration of FIG. 1A, a first method step of a method for producing a conversion element described herein is described in more detail. In the method step shown, a first cover body 1 with a first connecting surface 1a is provided. The first cover body 1 can be, for example, a glass plate.

A cavity 10 is formed in the first cover body 1 at the first connecting surface 1a. In the present case, the cavity 10 is a recess formed in the first cover body 1. The cavity 10 is enclosed, on the side surfaces 10b thereof, by the material of the first cover body 1. For example, the cavity 10 has been formed in the first cover body 1 using a rolling and/or etching technique.

In the region of the cavity 10, the first cover body 1 has a thickness reduced by the depth of the cavity. Outside the cavity 10, the first cover body 1 has a first thickness 1d. The depth of the cavity 10 can, for example, correspond to at least 10%, preferably, at least 20% of the first thickness 1d of the first cover body 1.

According to the schematic sectional illustration of FIG. 1B, a further method step of a method described herein is described in more detail. In the method step shown, the cavity 10 is filled with a filling material 30. The filling material 30 contains a conversion material 31 which can be, for example, wavelength-converting quantum dots and/or a wavelength-converting organic conversion material. After filling the cavity 10, the filling material 30 is cured.

The filling material 30 can in particular fill the cavity 10 completely. Here, it is possible that the cover surface 30a of the filling material 30 facing away from the first cover body 1 terminates flush with the first connecting surface 1a, if applicable. In other words, the connecting surface 1a and the cover surface 30a together form a planar surface.

According to the schematic sectional illustration of FIG. 1C, a final method step of a method for producing a conversion element described herein and an exemplary embodiment of a conversion element described herein is described in greater detail. In the method step shown, a second cover body 2 is attached to a side of the first cover body 1 that comprises the first connecting surface 1a with a second connecting surface 2a facing the first cover body 1 and is cohesively connected to the first cover body 1. The second cover body 2 can also be a glass plate.

Connecting the two cover bodies 1, 2 is effected by wringing, cold welding and/or laser welding. An atomic and/or molecular connection 122 is formed between the first connecting surface 1a and the second connecting surface 2a by wringing and/or cold welding. Here, the atomic and/or molecular connection 122 represents a mixture of the materials of the two cover bodies 1, 2 and thus is part of the two cover bodies 1, 2. In particular, the two connecting surfaces 2a, 2b are directly adjacent to one another at the place of the connection 122 and form the connection 122. Additionally, a weld seam 121 can be created when using laser welding. The weld seam 121 encloses the cavity 10 and/or the filling material 30 in the type of a frame.

The last method step shown in FIG. 1C results in a conversion element 3 having the components described already. The first cover body 1, the second cover body 2, and the cavity 10 filled with the filling material 30 together form the conversion element 3 then. The cavity 10 filled with the filling material 30 of the conversion element 3 can be hermetically sealed toward the outside by the first cover body 1 and the second cover body 2. Preferably, the cover surface 30a of the filling material 30 is in direct contact with the second connecting surface 2a of the second cover body 2.

According to the schematic sectional illustration of FIG. 2A, an optoelectronic component with a conversion element 3 described herein is described in greater detail. The optoelectronic component has a light-emitting component 4 with a light-emitting semiconductor chip 40, which can, for example, be an organic or inorganic light-emitting diode chip, and a housing 41. The housing 41 is, for example, a light-reflecting component which can be formed with a plastic material. The light-emitting semiconductor chip 40 is introduced into a recess 411 of the housing 41.

A light-transmissive connection layer 5 is attached to a light-exit surface 4a of the light-emitting semiconductor chip 40 facing away from the housing 41. The connection layer 5 can be formed with a silicone or a light-transmissive adhesive. The connection layer 5 completely covers all outer surfaces of the component 4 that comprise the light-exit surface 4a.

The first bottom surface 1c of the first cover body 1 facing away from the filling material 30 is directly adjacent to a joining surface 5a facing away from the light-exit surface 4a of the connection layer 5. In other words, the conversion element 3 is glued on the light-emitting component 4 by means of the connection layer 5. In particular, the conversion element 3 is glued on the light-exit surface 4a of the component 4. Here, as an alternative, it is possible (other than shown in FIG. 2A) that the conversion element 3 is glued on the light-exit surface 4a at the second bottom surface 2c of the second cover body 2 facing away from the first bottom surface 1c. The first bottom surface 1c faces away from the light-emitting semiconductor chip 40.

According to the schematic sectional illustration of FIG. 2B, a further exemplary embodiment of an optoelectronic component described herein with a conversion element 3 described herein is described in more detail. The exemplary embodiment shown differs from the one of FIG. 2a in that the conversion element 3 is applied to the housing body 41. The connection layer 5 is attached to the recess 411 of the housing body 41. The connection layer 5 preferably completely fills the recess 411. The conversion element 3 is, in places, in direct contact with a housing cover surface 41a facing away from the light-emitting semiconductor chip 40. In particular, the conversion element 3 completely covers the recess 411.

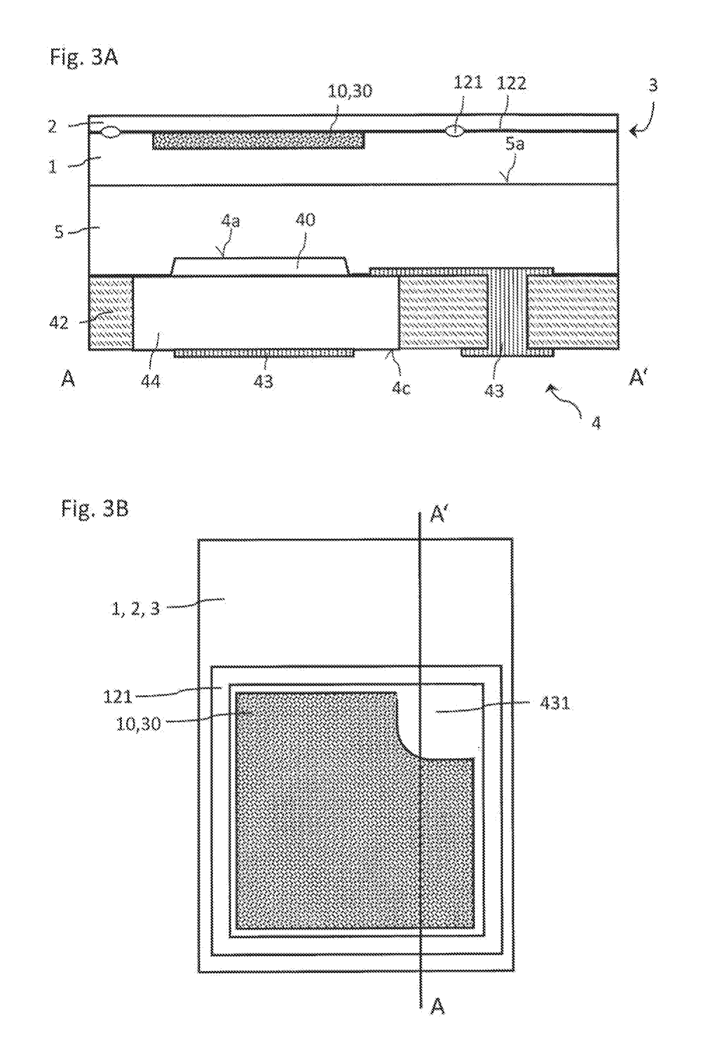

According to the schematic sectional illustration of FIG. 3A, a further exemplary embodiment of an optoelectronic component described herein with a conversion element 3 described herein is described in more detail. The section shown is effected along a connection line A-A′. The optoelectronic component of FIG. 3A comprises a light-emitting component 4 which in the present case is configured as a so-called “semiconductor chip in a frame” component.

The optoelectronic component comprises a light-emitting component 4 with a substrate 44 and a light-emitting semiconductor chip 40 applied to the substrate 44. Furthermore, the light-emitting component 4 comprises a shaped body 42 which laterally encloses the light-emitting semiconductor chip 40 and, at least in places, is in direct contact with the light-emitting semiconductor chip 40. The shaped body 42 can, for example, be formed with an epoxy resin or a silicone resin.

Additionally, the light-emitting component 4 comprises connections 43 which serve for electrically contacting the light-emitting semiconductor chip 40. The connections 43 are at least in places in direct contact with the light-emitting semiconductor chip 40. Furthermore, the connections 43 cover the shaped body 42 and the substrate 44 at least in places. Here, it is possible that at least one connection 43 extends through the shaped body 42 in a vertical direction. As a result, a direct electrical contacting of said at least one connection 43 at a bottom surface 4c of the light-emitting component 4 facing away from the connection layer 5 is enabled.

The optoelectronic component of FIG. 3A further comprises the connection layer 5, which completely covers the light-emitting component 4 at the side thereof that comprises the light-exit surface 4a. Here, the connection layer 5 can at least in places be in direct contact with the light-exit surface 4a, the shaped body 42 and the connections 43.

The conversion element 3 is adjacent to the joining surface 5a of the connection layer 5 facing away from the component 4. The filling material 30 of the conversion element 3 preferably has at least the lateral extent of the semiconductor chip 40. In other words, the filling material 30 completely covers the semiconductor chip 40 in a plan view from a vertical direction.

According to the schematic sectional illustration of FIG. 3B, a further exemplary embodiment of an optoelectronic component described herein is described in more detail. FIG. 3B shows the component of FIG. 3A in a plan view of the conversion element 3 from above. The section illustrated in FIG. 3A is effected along the connection line A-A′.

The filling material 30 is formed in the type of a rectangle in the plan view, and comprises a cut-out 431. The cut-out 431 may already be left-out e.g. in the production method during generation of the cavity 10. For example, an electrical contacting of the light-emitting semiconductor chip 40 can be effected with a bonding wire in the cut-out 431. Furthermore, the filling material 30 is laterally completely enclosed by a weld seam 121. The two cover bodies 1, 2 have a greater lateral extent than the filling material 30.

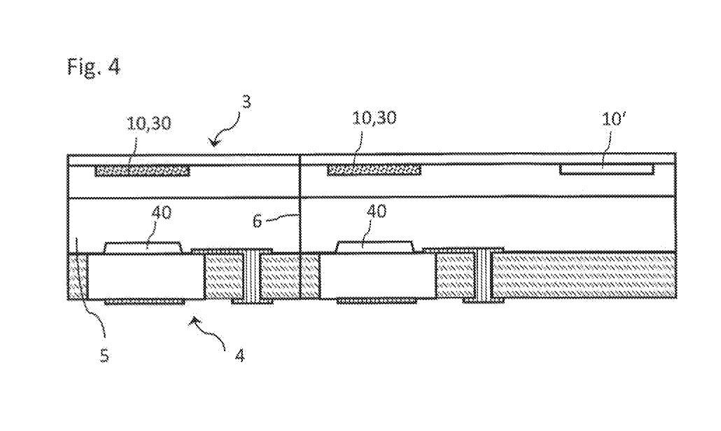

According to the schematic sectional illustration of FIG. 4, a further exemplary embodiment of an optoelectronic component described herein is described in more detail. In the exemplary embodiment shown here, two components are connected according to FIG. 3A. The components can be singulated at the singulation line 6 shown. The conversion element 3 comprises a plurality of cavities 10, 10′. Here, the first cavities 10 are filled with the filling material 30. At least one second cavity 10′ is not filled with the filling material 30. No semiconductor chip 40 is assigned to this second cavity 10′. The second cavity 10′ is located in the periphery of the light-emitting semiconductor chip 40. In other words, no light-emitting semiconductor chip 40 is assigned to the second cavity 10′. Here, only scattering light and/or radiation with a large opening angle can enter the second cavity 10′. The second cavity 10′ may then have the function of a diffuser lens and can, for example, divert scattering light of the semiconductor chip 40 away from a main radiation direction. Thereby, the radiation characteristic of the optoelectronic component can be improved.

The invention is not limited to the exemplary embodiments by the description on the basis of the exemplary embodiments. Rather, the invention comprises each new feature as well as each combination of features, in particular including each combination of features in the patent claims, even if this feature or this combination is not per se explicitly indicated in the patent claims or exemplary embodiments.

This patent application claims priority of German patent application 10 2014 116 778.3, the disclosure content of which is incorporated herein by reference.

### LIST OF REFERENCE NUMERALS

1 first cover body
1a first connecting surface
1c first bottom surface
1d first thickness
2 second cover body
2a second connecting surface
2c second bottom surface
10, 10′ cavity
10b side surfaces of the cavity
121 weld seam
122 connection
3 conversion element
30a cover surface
30 filling material
31 conversion material
4 light-emitting component
4a light-exit surface
4c bottom surface
40 light-emitting semiconductor chip
41 housing
41a housing cover surface
411 recess
42 shaped body
43 connections
431 cut-out
44 substrate
5 connection layer
5a joining surface
6 singulation line

1. Method for producing a conversion element, comprising the following steps:
A) providing a first cover body with a first connecting surface and second cover body,
B) forming at least one cavity in the first cover body on the first connecting surface,
C) filling the at least one cavity with a filling material, which comprises a conversion material,
D) applying the second cover body to the first connecting surface of the first cover body,
E) cohesively connecting the first cover body and the second cover body.

2. Method according to claim 1, wherein the water vapor transmission rate into the cavity and/or into the filling material is no more than 1×10⁻³ g/m²/day, preferably no more than 3×10⁻⁴ g/m²/day.

3. Method according to claim 1, wherein the cavity has a depth which corresponds to at least 10% and no more than 90% of the thickness of the first cover body.

4. Method according to claim 1, wherein the conversion material comprises wavelength-converting quantum dots or consists of wavelength-converting quantum dots.

5. Method according to claim 1, wherein filling in step c) is effected in such a way that
a cover surface of the filling material facing away from the first cover body terminates flush with the first connection surface of the first cover body, and
the second cover body is in direct contact with the cover surface after the connection in step E).

6. Method according to claim 1, wherein the connection of the first cover body and the second cover body in step E) is effected by means of wringing and/or cold welding.

7. Method according to claim 6, wherein the first connecting surface of the first cover body and a second connecting surface of the second cover body facing the first cover body are treated with a solvent prior to the application in step D) and/or are heated at a temperature of at least 22° C. and no more than 24° C. after the application in step D).

8. Method according to claim 1, wherein the application of the second cover body to the first cover body in step D) is effected at an ambient pressure of at least 10⁻¹ Pa and no more than 10³ Pa.

9. Method according to claim 1, wherein a plurality of laterally spaced cavities is formed in the first cover body, wherein at least one of the plurality of cavities remains free from the filling material.

10. Method according to claim 1, wherein the connection in step E) is effected under exclusion of a joining material, in particular an adhesive.

11. Method according to claim 1, wherein the connection in step E) is effected by laser welding with a pulsed laser beam.

12. Conversion element, comprising:
a first cover body with a first connecting surface,
a second cover body with a second connecting surface facing the first cover body, and
a filling material, which comprises a conversion material, wherein
the first cover body comprises a cavity on the first connecting surface into which the filling material is introduced, and
the first cover body and the second cover body are cohesively connected to one another.

13. Conversion element according to claim 12, in which a weld seam is arranged between the first cover body and the second cover body, which encloses the filling material in the type of a frame.

14. Conversion element according to claim 12, in which the filling material has a thickness which corresponds to at least 10% and no more than 90% of the thickness of the first cover body.

15. Conversion element according to claim 12, in which a plurality of cavities is present, wherein at least a plurality of cavities is free from the filling material.

16. Conversion element according to claim 12, in which the first connecting surface and the second connecting surface are free from a joining material and are directly adjacent to one another.

17. Optoelectronic component, comprising:
at least one conversion element according to claim 12,
at least one light-emitting component having a light exit surface, and
a light-transmissive connection layer, wherein
the connection layer entirely covers the component on its side comprising the light exit surface, and
an outer surface of the conversion element is directly adjacent to a joining surface of the connection layer facing away from the light-emitting component.

18. Optoelectronic component according to claim 17, in which the first cover body of the conversion element comprises at least one first cavity and at least one second cavity laterally spaced apart from the first cavity, wherein
the filling material is introduced in the at least one first cavity,
the at least one second cavity is filled with air and/or a gas,
the filling material of the first cavity is arranged directly after the light exit surface and entirely covers the light exit surface, and
the second cavity is arranged laterally spaced from the light-emitting component.

19. Method according to claim 1, wherein the first cover body and the second cover body are glass plates, respectively.
